(19) United States
(12) Patent Application Publication
(10) Pub. No.: US 2016/0070416 A1
(43) Pub. Date: Mar. 10, 2016

(54) A Coupling Arrangement, A Panel and a Touch Sensitive System

(71) Applicant: FLATFROG LABORATORIES AB, Lund (SE)

(72) Inventor: Ola Wassvik, Brösarp (SE)

(21) Appl. No.: 14/783,784

(22) PCT Filed: Apr. 9, 2014
(86) PCT No.: PCT/SE2014/050438

§ 371 Date: Oct. 9, 2015

(30) Foreign Application Priority Data
Apr. 11, 2013 (SE) 1350461-8

(51) Int. Cl. G06F 3/042; H05K 1/02

(52) U.S. Cl. CPC G06F 3/0421; H05K 1/0296; H05K 1/0274; H05K 1/028; G06F 2203/04109; G06F 2203/04103

(57) ABSTRACT

The disclosure relates to a coupling arrangement comprising a printed circuit assembly, PCA, comprising: a printed circuit board, PCB; a group of components comprising an emitter, a detector and an integrated circuit, IC, wherein the components are electrically bonded to the PCB, and the emitter and the detector are electrically connected to the integrated circuit via the PCB, the integrated circuit is further configured to control operation of the emitter and the detector in the same group; and a first coating covering at least one of the components in the group; wherein the coupling arrangement further comprises a volume element, wherein the first coating and the volume element are made of optically transparent materials, and wherein the volume element is arranged to at least partly cover the first coating. The disclosure also relates to a touch sensitive panel and a touch sensitive system.

### CROSS-REFERENCE TO RELATED APPLICATIONS

The present application claims the benefit of Swedish patent application No. 1350461-8, filed 11 Apr. 2013.

### FIELD OF THE INVENTION

The present invention relates to a coupling arrangement for injecting light into a panel, and use of the coupling arrangement with a panel and in a touch sensitive system according to the preamble of the independent claims.

### BACKGROUND OF THE INVENTION

Touch sensing systems (“touch systems”) are in widespread use in a variety of applications. Typically, the touch systems are actuated by a touch object such as a finger or stylus, either in direct contact, or through proximity (i.e. without contact), with a touch surface. Touch systems are for example used as touch pads of laptop computers, in control panels, and as overlays to displays on e.g. hand held devices, such as mobile telephones. A touch panel that is overlaid on or integrated in a display is also denoted a “touch screen”. Many other applications are known in the art. To an increasing extent, touch systems are designed to be able to detect two or more touches simultaneously, this capability often being referred to as “multi-touch” in the art.

WO2011/028169 and WO2011/049512 disclose multi-touch systems that are based on frustrated total internal reflection (FTIR). Light sheets are coupled into a panel by emitters to propagate inside the panel by total internal reflection (TIR). When an object comes into contact with a touch surface of the panel, the propagating light is attenuated at the point of touch. The transmitted light is measured at a plurality of outcoupling points by one or more light detectors. The signals from the light detectors are processed for input into an image reconstruction algorithm that generates a 2D representation of interaction across the touch surface. This enables repeated determination of current position/size/shape of touches in the 2D representation while one or more users interact with the touch surface. Examples of such touch systems are found in e.g. U.S. Pat. No. 3,673,327, U.S. Pat. No. 4,254,333 and U.S. Pat. No. 6,972,753.

The emitters and detectors of the system should be connected to external electrical circuitry. These components are typically integrated into and electrically connected to a printed circuit board, a PCB, and placed along the periphery of the touch panel.

Different solutions exist to integrate the components to the PCB. One category of solutions makes use of wire bonding to connect the component to external circuitry. One solution in this category use FR-4, a composite material composed of woven fiberglass cloth. A thin layer of copper foil is laminated to one, or both sides of an FR-4 glass epoxy panel. These are commonly referred to as “copperclad laminates”. A component is connected via bonding wires to a FR-4 panel and forms with a molding a substrate package. The substrate package is in turn connected to the PCB via connections on the package.

Another solution in this category makes use of a lead frame package, where the component is connected via bonding wires to a lead frame. The component and bonding wires are protected by a molding. The lead frame is in turn connected to the PCB.

Another category of solutions for connecting components to external circuitry is to use flip chip, also known as controlled collapse chip connection, or its acronym, C4. The solution makes use of solder bumps that has been deposited to the external circuitry. In order to mount the chip to external circuitry, e.g. a PCB, it is flipped over so that its top side faces down, and aligned so that its pads align with matching pads on the external circuit, and then the solder is flowed to complete the interconnect.

The components and its wire bonding, if used, can be protected by so called glob-top coating. Glob top is a coating consisting of a drop of specially formulated resin deposited over the chip and its wire bonds, to provide mechanical support and exclude contaminations such as fingerprint residues which could disrupt circuit operation.

When having components such as emitters and detectors that shall be used in a touch sensitive system, care must be taken such that light from the emitters is correctly injected into the panel, and such that the detectors can correctly detect light propagating in the panel. To achieve this, the emitters and detectors may be covered by a coating of optically transparent material acting as a filler between the emitters/detectors and the panel. The coating however has to have a certain size to allow correct injection of light into the panel. With a PCB holding the emitters and detectors, the dimensions becomes unpractical. Further, the cost of the coating is relatively expensive.

It is thus an object of the invention to reduce the cost for the system and to provide a manageable assembly with the components. It is a further object to provide an incoupling solution to the system.

### SUMMARY OF THE INVENTION

According to a first aspect, the object is achieved by a coupling arrangement comprising a printed circuit assembly, PCA, comprising a printed circuit board, PCB; a group of components comprising an emitter, a detector and an integrated circuit, IC, wherein the components are electrically bonded to the PCB, and the emitter and the detector are electrically connected to the integrated circuit via the PCB. The integrated circuit is further configured to control operation of the emitter and the detector in the same group. A first coating covers at least one of the components in the group. The coupling arrangement further comprises a volume element, wherein the first coating and the volume element are made of optically transparent materials, and wherein the volume element is arranged to at least partly cover the first coating.

With such a coupling arrangement, less first coating has to be used as the volume element substitute some of the first coating. Costs can be reduced as the cost for a volume element is lower than having more first coating.

The volume element can act as a guide on a panel for the PCA, and time consuming positioning of the PCA can be removed or at least reduced.

According to one embodiment, the optically transparent materials are configured to be transparent to infra-red light.

According to one embodiment, the optically transparent materials are configured to block visible light.

According to one embodiment, the first coating has a box-shaped form with two longitudinal side surfaces and a top surface, wherein at least one of the side surfaces and top surface is a substantially planar surface.

According to one embodiment, the first coating is a glob-top coating.

According to one embodiment, the volume element has a box-shaped form corresponding to some extent to a shape of the first coating.

According to one embodiment, the PCB has a longitudinal extension.

According to one embodiment, the PCB comprises a plurality of groups of components, wherein the groups of components are positioned at a distance from each other along the longitudinal extension of the PCB.

According to one embodiment, the volume element has a longitudinal extension corresponding to the longitudinal extension of the PCB.

According to one embodiment, the PCA comprises an adhesive layer between the volume element and the first coating.

According to one embodiment, the PCB is a flexible printed circuit board.

According to a second aspect, the object is at least partly achieved by a touch sensitive panel comprises a coupling arrangement as herein explained.

According to a third aspect, the object is at least partly achieved with a touch sensitive system comprising a touch sensitive panel, wherein the printed circuit assembly is attached to the touch sensitive panel along the periphery of said touch surface; the system comprises a control unit connected to at least one integrated circuit in a group, and configured to control operation of the components in each group.

The touch sensitive system is according to one embodiment based on Frustrated Total Internal Reflection, FTIR.

Preferred embodiments are set forth in the dependent claims and in the detailed description.

### SHORT DESCRIPTION OF THE APPENDED DRAWINGS

Below the invention will be described in detail with reference to the appended figures, of which:

FIG. 1 illustrates a side view of a touch arrangement based on FTIR.

FIG. 2 illustrates a top view of the touch arrangement in FIG. 1.

FIGS. 3A and 3B illustrates a printed circuit board according to various embodiments of the invention.

FIGS. 4A, 4B and 4C illustrates different coupling arrangements according to some embodiments of the invention.

FIG. 5 illustrates a touch sensitive system according to some embodiments of the invention.

FIG. 6 illustrates a view from below of the touch sensitive system.

FIG. 7 illustrates a method for fabricating a printed circuit board according to some embodiments of the invention.

### DETAILED DESCRIPTION OF PREFERRED EMBODIMENTS OF THE INVENTION

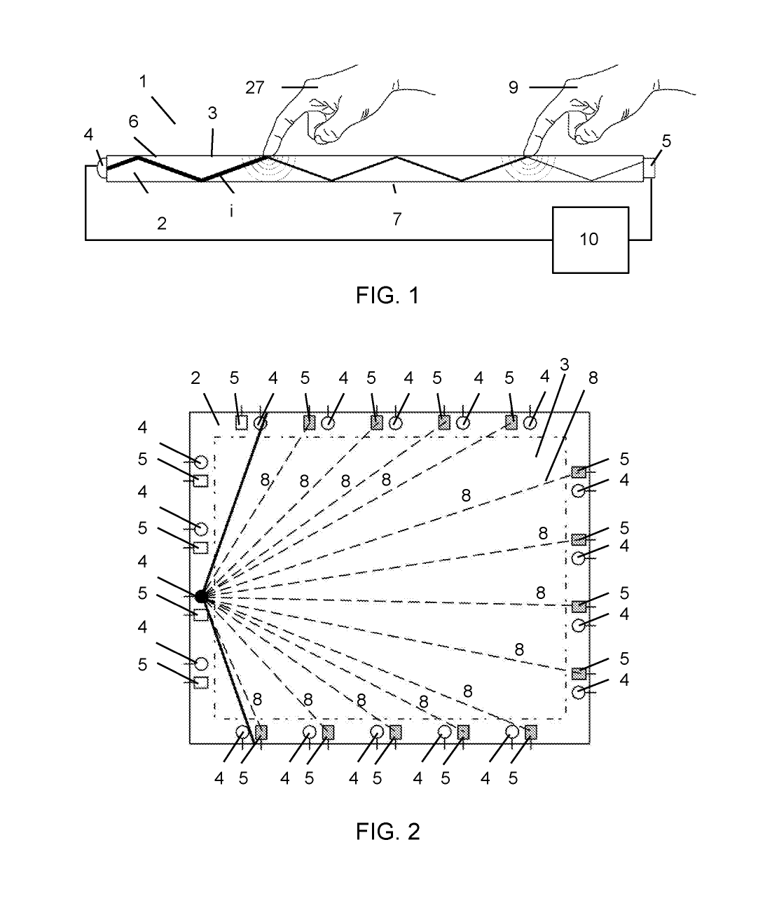

FIGS. 1 and 2 illustrates a side view and a top view of an example embodiment of a touch arrangement 1 to be used in a touch-sensitive system 11 that is based on the concept of FTIR (Frustrated Total Internal Reflection), also denoted “FTIR system”. The touch arrangement 1 operates by transmitting light inside a touch sensitive panel 2, from light emitters 4 to light sensors or detectors 5, so as to illuminate a touch surface 3 from within the panel 2. The panel 2 is made of solid material in one or more layers and may have any shape. The panel 2 defines an internal radiation propagation channel, in which light propagates by internal reflections. In the example of FIG. 1, the propagation channel is defined between two boundary surfaces 6, 7 of the panel 2, thus a top surface 6 and a bottom surface 7, where the top surface 6 allows the propagating light to interact with touching objects 27, 9 and thereby defines the touch surface 3. This is achieved by injecting the light into the panel 2 such that the light is reflected by total internal reflection (TIR) in the touch surface 3 as it propagates through the panel 2. The light may be reflected by TIR in the bottom surface 7 or against a reflective coating thereon. It is also conceivable that the propagation channel is spaced from the bottom surface 7, e.g. if the panel 2 comprises multiple layers of different materials. The panel 2 may be designed to be overlaid on or integrated into a display device or monitor.

The arrangement 1 allows one or several objects 27, 9 that is brought into close vicinity of, or in contact with, the touch surface 3 to interact with the propagating light at the point of touch. In this interaction, part of the light may be scattered by the object 27, 9, part of the light may be absorbed by the object 27, 9 and part of the light may continue to propagate in its original direction across the panel 2. Thus, the touching object 27, 9 causes a local frustration of the total internal reflection, which leads to a decrease in the energy (power/intensity) of the transmitted light, as indicated by the thinned lines downstream of the touching objects 27, 9 in FIG. 1. If two objects 27 and 9 happen to be placed after each other along a light path i from an emitter 4 to a detector 5, part of the light will interact with both these objects 27, 9. Provided that the light energy is sufficient, a remainder of the light will interact with both objects 27, 9 and generate an output signal that allows both interactions (touch inputs) to be identified. The output signal is received to a control unit 10 which processes the output signal to detect interaction with the touching object(s) 27, 9.

As illustrated in FIG. 2, the emitters 4 are distributed along the perimeter of the touch surface 3 of the panel 2. The emitters 4 generate a corresponding number of light sheets inside the panel 2. Each emitter 4 generates a beam of light that expands in the plane of the panel 2 while propagating in the panel 2. Each beam propagates from one or more entry or incoupling points on the panel 2. The detectors 5 are distributed along the perimeter of the touch surface 3 of the panel 2 to receive the light from the emitters 4 at a number of spaced-apart outcoupling points on the panel 2. The emitters 4 and detectors 5 are here grouped in couples with one emitter 4 and one detector 5 side by side, but the distribution could be different. For example, two or three emitters 4 located side by side, and two or three detectors 5 located side by side could be alternately distributed along the perimeter of the touch surface 3. A light path from an emitter 4 to a detector 5 is defined as a detection line 8. In the figure the detection lines 8 from one emitter 4 to a plurality of detectors 5 are denoted as dotted lines. The plurality of detectors 5 are shaded to indicate their participation in receiving light at ends of the detection lines 8.

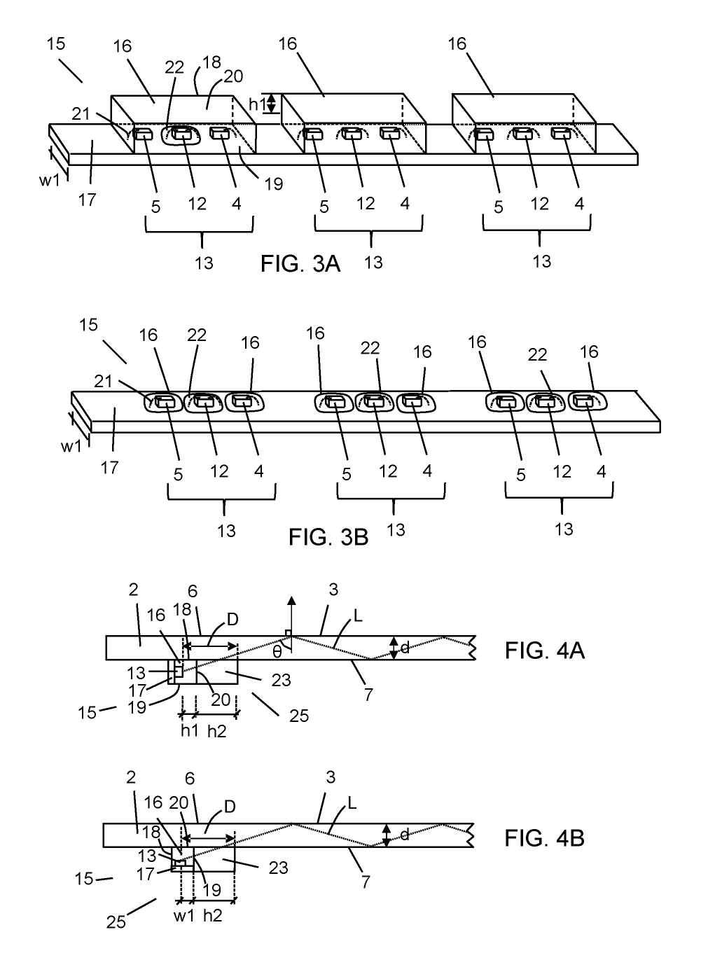

In FIG. 3A an example of a printed circuit assembly, PCA, 15 is shown. The PCA 15 comprises a printed circuit board, PCB, 17, and at least one group 13 of components comprising an emitter 4, a detector 5 and an integrated circuit, IC, 12. In the FIG. 3A three groups 13 of components are illustrated, but it is understood that the number can be more or less. The PCB 17 may have a longitudinal extension and comprise a plurality of groups 13 of components. The groups 13 of components are then positioned at a distance from each other along the longitudinal extension of the PCB 17. The PCB 17 may be a flexible printed circuit board. The term “flexible” means that the assembled PCB 17, thus the PCA 15, will be able to bend without breaking. A suitable material for the flexible printed circuit board is e.g. flexible plastic substrates such as polyimide, polymer thermoplastics such as PEEK (Polyether ether ketone), or polyester film. The PCA 15 may be used with the arrangement 1 in FIGS. 1 and 2 to inject light into the panel 2 and to detect the same. The components may be electrically bonded to the PCB 17 via wire bonding where one or several wires 21 from the components are connected to the PCB 17 via soldering pads. Alternatively, one or several of the components may be electrically bonded to the PCB 17 via so called flip chip bonding, via matching soldering pads on the PCB 17 and the component(s). In any of the alternatives, the components are connected directly to the PCB 17 without any intermediate attachment means. The emitter 4 and the detector 5 are electrically connected to the integrated circuit 12 via the PCB 17. The integrated circuit 12 is configured to control operation of the emitter 4 and the detector 5 in the same group 13. The PCB 17 is thus used to mechanically support the components and to electrically connect the components. To electrically connect the components, the PCB 17 may comprise conductive pathways, tracks or signal traces e.g. etched from copper sheets laminated onto a non-conductive substrate.

The PCA 15 further comprises a first coating 16 covering at least one of the components in the group 13. The emitter(s) 4 and the detector(s) 5 in each group 13 are preferably covered with a first coating 16. The first coating 16 is made of an optically transparent material, such that the emitter 4 can emit light into the panel 2 via the first coating 16, and the detector 5 can detect light propagating in the panel 2 via the first coating 16. The optically transparent material is preferably transparent to near infra-red light, thus, it lets through electromagnetic radiation with the wavelengths from 0.74 μm to 1.4 μm. Example of such materials are e.g. a polymer, epoxy, etc. The first coating 16 may additionally comprise a material that is blocking visible light, thus acting as a detector filter to ambient light.

The integrated circuit 12 may be covered with a second coating 22. The second coating 22 may be located between the first coating 16 and the integrated circuit 12 as illustrated in FIG. 3A. In another embodiment the integrated circuit 12 is not covered with a first coating 16, but only the second coating 22. The second coating 22 is only illustrated on one of the integrated circuits 12 on the PCA 15, but it is understood that all the integrated circuits 12 on the PCA 15 may be covered with a second coating 22. The second coating 22 comprises an optically non-transparent material, such that the integrated circuit 12 will be protected from light. Light might otherwise disturb the function of the integrated circuit 12. The second coating 22 may be deposited to the integrated circuit 12 as a so called glob top coating. The second coating 22 is then a glob top coating consisting of a drop of e.g. specially formulated resin with filter characteristics such that no light is allowed to pass. For example may a black color be used as a filter agent mixed to the resin.

The first coating 16 may have a box-shaped form with two longitudinal side surfaces 18, 19 and a top surface 20. At least one of the side surfaces 18, 19 and top surface 20 is a substantially planar surface, such that it can act as an optically surface and lie against the panel 2. The first coating 16 here has a height h1 extending from the top of one of the components, e.g. the emitter 4 to the top surface 20.

In FIG. 3B another example of a printed circuit assembly, PCA, 15 is shown. The embodiment is essentially the same as the embodiment shown in FIG. 3A, except that the first coating 16 here is a glob top coating on the emitters 4 and detectors 5. The integrated circuit 12 is covered with a second coating 22 that also is a glob top coating but has different characteristics than the first coating 16. The first coating 16 should be transparent to light, e.g. infra red light, and the second coating 22 should block light to protect the integrated circuit 12.

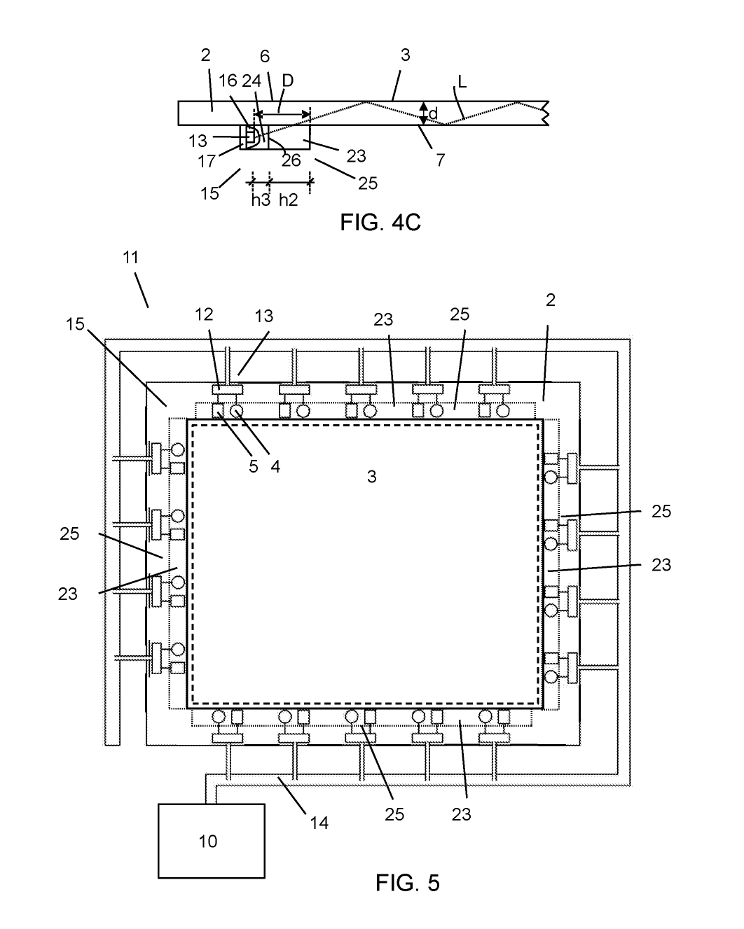

The PCA 15 can be attached to a volume element 23 to form a coupling arrangement 25. The volume element 23 is not shown in FIGS. 3A and 3B, but is illustrated in the FIGS. 4A-4C. In these figures, three different coupling arrangements 25 are illustrated in cross section. One component in a group 13 is shown, as well as the first coating 16, the PCB 17 and the volume element 23. Light from an emitter 4 and light to a detector 5 in the group 13 may then be transmitted into and out of the panel 2 via the surfaces that faces the bottom surface 7. A coupling arrangements 25 is thus used to introduce light L into the panel 2, and to receive light propagating in the panel 2. Light should be introduced into the panel 2 at an angle θ to the normal of the panel 2 which is larger than a critical angle at a light injection site of the panel 2. Then internal reflection between the upper surface 6 and bottom surface 7 caused by total internal reflection (TIR) can be sustained. The critical angle is governed by the refractive indexes of the material receiving the light at the injection site and the surrounding material, as is well-known to the skilled person.

To be able to introduce light into the panel 2 at an angle θ larger than the critical angle, the light from the emitter 4 must be able to travel via an optical medium a certain length before it reaches the panel 2. By having a volume element 23 as an optical medium, the height of the PCA 15 can be kept low, but the light L can still travel in the optical medium such that it can reach the panel 2 in angles θ larger than the critical angle.

In the following text, further alternative coupling arrangements 25 will be explained. The first coating 16 and the volume element 23 are made of optically transparent material. The optically transparent materials are preferably transparent to infra-red light. According to one embodiment, the optically transparent materials are configured to block visible light. The optically transparent materials may thus both be transparent to infra-red light and block visible light. The volume element 23 is here illustrated to have a box-shaped form corresponding to some extent to a shape of the first coating 16 as will be illustrated with reference to FIGS. 4A-4C.

As can be seen from the FIGS. 4A-4C, the volume element 23 is arranged to at least partly cover the first coating 16. If the first coating 16 is arranged with a top surface 20 as illustrated in the FIGS. 4A and 4B, the volume element 23 may be configured to cover the total top surface 20. If the first coating 16 is e.g. a glob top and has a round surface as illustrated in FIGS. 3B and 4C, the volume element 23 may be configured to receive the glob top and let the glob top sink into the material of the volume element 23 such that the volume element 23 will constitute a bridge between the glob top and the panel 2 and provide the PCA 15 with a planar surface that can be aligned to the bottom surface 7 of the panel 2. Alternatively, an intermediate coating 24 as illustrated in FIG. 4C may have the characteristics of allowing the glob top to sink into the material of the intermediate coating 24. The volume element 23 may then be attached to the intermediate coating 24. The material of the volume element 23 or the intermediate coating 24 may then be e.g. an acrylate. If the volume element 23 instead should be more rigid, it can be made of another kind of plastics or polymer.

The volume element 23 (and when used also the intermediate coating 24), thus extends the optical way the light L can travel from the emitters 4 before it reaches the panel 2 and to the detectors 5. As illustrated in the figures, the panel 2 has a thickness d. The height of the first coating 16 extending from the top of a component, e.g. the emitter 4 or detector 5, to the top surface 20 is h1, and the height of the volume element 23 is h2. To provide an optical path for the light that is great enough, in the embodiment illustrated in FIG. 4A where PCA 15 is horizontally aligned to the panel 2, the heights h1 and h2 should together have an extension D of at least 2-4×d. The PCB 17 is here placed in a direction of the periphery of the panel 2. In the embodiment illustrated in FIG. 4B the PCA 15 is vertically aligned to the panel 2, and is attached to the volume element 23 along one of the side surfaces 18, 19. The PCA 15 has a width w1 extending from a component, e.g. an emitter 4 or detector 5, to one of the side surfaces 18, 19. The width w1 and the height h2 of the volume element thus has to be at least D. The PCB 17 is here placed in a direction away from the bottom surface 7 of the panel 2. In FIG. 4C, the PCA 15 is again horizontally aligned to the panel 2. The intermediate coating 24 has a height h3 extending from the component, e.g. emitter 4 or detector 5 to a top surface 26 of the intermediate layer 24 facing the volume element 23, and the volume element 23 has a height h2. The sum of the heights h2 and h3 should then be at least D. D is thus the smallest extension the planar surface of the coupling arrangement 25 facing the bottom surface 7 must have to provide an optical path that makes sure that enough light is introduced into the panel 2.

The side surface 18, 19 or top surface 20 that should be aligned to the bottom surface 7 may have a light blocking coating, such that the components, e.g. the detectors 5, can be protected from light introduced mainly along the normal of the panel 2. Care must be taken when providing the surface with a light blocking coating, such that emitted light or light that shall be detected is not blocked. As the height h1 or width w1 of the first coating 16 now is small, the whole surface 18, 19. 20 can be covered with the light blocking coating without any need for precision.

The volume element 23 is in one embodiment attached to the panel 2 before it is attached to the PCA 15. The volume element 23 may then act as a mounting support for the PCA 15.

The volume element 23 may have a longitudinal extension corresponding to the longitudinal extension of the PCB 17. The volume element 23 may alternatively be divided in parts where the parts are placed on the panel 2 or the PCA 15 such that the emitters 4 and the detectors 5 can emit/detect light to/from the panel 2 via the volume element 23. The space between each part will allow the volume element 23 to e.g. expand when exerted to thermal stress.

An adhering means such as an adhesive layer, glue or double coated adhesive tape may be used between the PCA 15 and the volume element 23 (e.g. between the first coating 16 and the volume element 23) and/or between the volume element 23 and the bottom surface 7 of the panel 2 to attach the PCA 15 to the volume element 23 and the volume element 23 to the panel 2. The adhering means may also act as a filler to fill in any irregularities in the surfaces to create a tight attachment.

The coupling arrangement 25 with a plurality of groups 13 of components may thus be located around the periphery of the touch surface 3 or the panel 2, such that light from emitters 4 can be injected into the panel 2 etc. as previously explained. The touch sensitive panel 2 may thus comprise a coupling arrangement 25 according to any of the embodiments as has been previously explained. This is illustrated in FIG. 5, where a touch sensitive system 11 comprising a touch sensitive panel 2 defining a touch surface 3 is shown. The system 11 comprises a panel 2 with a coupling arrangement 25 according to any of the embodiments as has been previously explained. The coupling arrangement 25 is attached to the touch sensitive panel 2 along the periphery of the touch surface 3. The system 11 further comprises a control unit 10. The control unit 10 may be connected to one or several integrated circuits 12 via a buss 14, daisy chain or via other wired connections. The integrated circuits 12 may be connected in series, or in parallel, via the buss 14, daisy chain or other wired connection to the one or several integrated circuits 12 connected to the control unit 10. The integrated circuits 12 may be arranged to communicate via a local area network, e.g. a token ring network. The control unit 10 configured to control operation of the components in each group 13. The control unit 10 is further configured to receive detection data from the detectors 5 via e.g. one or several signals, and to analyse the detection data to detect interaction with the touch surface 3. The touch sensitive system 11 is according to one embodiment based on Frustrated Total Internal Reflection, FTIR.

A screen or display may be integrated with the panel 2, e.g. attached to the bottom surface 7 of the panel 2. The coupling arrangement is then preferably placed along the panel 2 outside the extension of the screen or display. If e.g. an 11 inch screen or display is used, the number of emitters 4 may be between 40-80, and the number of detectors 5 may be between 40-80 to cover the total area of the screen or display. Each integrated circuit 12 may be connected to 1-4 emitters 4 each, and 1-4 detectors 5. According to one embodiment, only one emitter 4 and one detector 5 is connected to each integrated circuit 12.

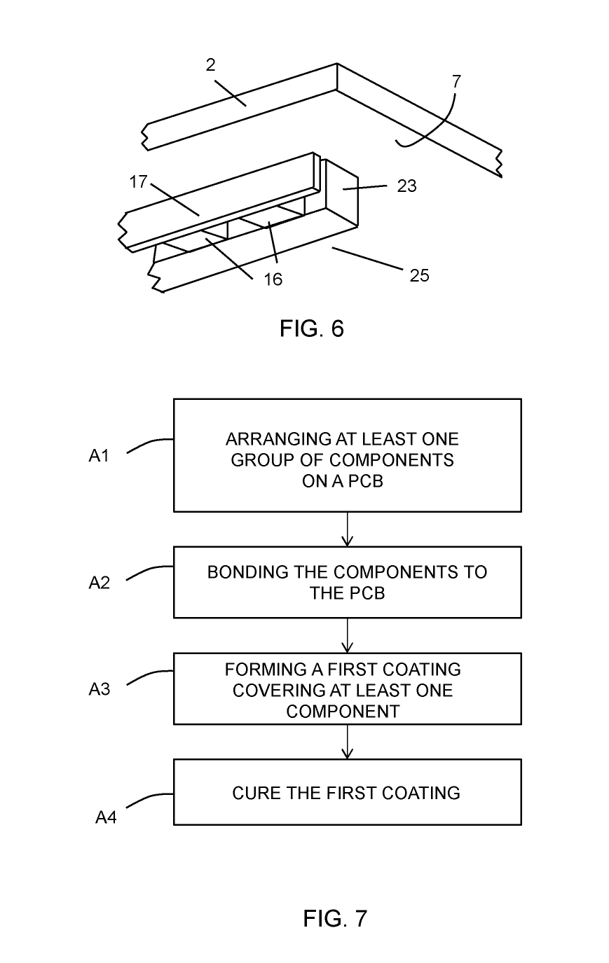

FIG. 6 illustrates a panel 2 seen from below such that the bottom surface 7 can be seen. The coupling arrangement 25 is here visible, illustrating the PCA 15 attached to the volume element 23. The PCB 17 has here a longitudinal extension, and is facing away from the touch surface 3 (not shown), towards the periphery of the panel 2.

The disclosure also relates to a method for fabricating a printed circuit assembly 15. The method is here explained with reference to the flowchart in FIG. 7. The method comprises arranging at least one group of components 13 comprising an emitter 4, a detector 5 and an integrated circuit, IC, 12 on a printed circuit board, PCB, 17 (A1). The components may be arranged in different manners, for example side by side as illustrated in FIGS. 3A and 3B, or with the integrated circuit 12 in parallel with the emitter 4 and detector 5 as shown in FIG. 5. Other arrangements are also feasible, and the illustrated arrangements are only for illustration. The arrangement preferably matches how the components later on shall be located in the system 11. For example, the arrangement may include the distance between each group 13 of components, and distances between each of the components in a group 13. The PCB 17 is prepared with soldering spots and conductive pathways etc. to enable electrical connection between the PCB 17 and the components, and between the components. The components are thus arranged such that they match with the premade soldering spots in a pre-defined pattern. Thus, there is no need for any intermediate layer between the components and the PCB 17, or any intermediate step of attaching the components to any holding means or other attachments in a package. The components of at least one group 13 are then electrically bonded to the PCB 17, and the emitter 4 and the detector 5 are electrically connected to the integrated circuit 12 via the PCB 17 (A2). This step can be made by e.g. heating the soldering spots. Hereafter, a first coating 16 is formed covering at least one of the components, wherein the first coating 16 is made of an optically transparent material (A3). The first coating 16 may be formed to have a box-shaped form as illustrated in FIG. 3A, with two longitudinal side surfaces 18, 19 and a top surface 20, wherein at least one of the side surfaces 18, 19 and top surface 20 is a substantially planar surface. This box-shaped form may be achieved with a method called “dam and fill” used to encapsulate components. To create a dam, a rectangle of fluid is dispensed around the component. This fluid is typically high viscosity in nature, so once it is dispensed, it does not flow. Liquid fill encapsulant, i.e. the material of the first coating, is then dispensed over the component and its wires, if any, to encapsulate them. The dam will keep the fluid in place. Another alternative is to cover the component with a box-like form, and to inject encapsulant into the form. The first coating 16 may instead be formed as a glob, e.g. a glob-top coating. The first coating 16 is then cured (A4). Curing can be made by e.g. heating, or using ultraviolet (UV) radiation.

The present invention is not limited to the above-described preferred embodiments. Various alternatives, modifications and equivalents may be used. For example, the panel 2 may be formed such that the panel 2 comprises the volume element 23. The panel 2 and the volume element 23 may also be moulded as one unit. The panel 2 and the volume element 23 may then be moulded of a plastic or glass. Alternatively, volume element 23 and the panel 2 may be moulded separately in a first step, and attached to each other in a second step. Therefore, the above embodiments should not be taken as limiting the scope of the invention, which is defined by the appending claims.

1. A coupling arrangement comprising a printed circuit assembly (PCA), comprising:
a printed circuit board (PCB);
a group of components comprising an emitter, a detector and an integrated circuit, wherein the components are electrically bonded to the PCB, the emitter and the detector are electrically connected to the integrated circuit via the PCB, and the integrated circuit is configured to control operation of the emitter and the detector in the group; and
a first coating covering at least one of the components in the group,
wherein the coupling arrangement further comprises a volume element, wherein the first coating and the volume element comprise optically transparent materials, and wherein the volume element is arranged to at least partly cover the first coating.

2. The coupling arrangement according to claim 1, wherein the optically transparent materials are configured to be transparent to infra-red light.

3. The coupling arrangement according to claim 1, wherein the optically transparent materials are configured to block visible light.

4. The coupling arrangement according to claim 1, wherein the first coating has a box-shaped form with two longitudinal side surfaces and a top surface, wherein at least one of the side surfaces, and top surface is a substantially planar surface.

5. The coupling arrangement according to claim 1, wherein the first coating is a glob-top coating.

6. The coupling arrangement according to claim 1, wherein the volume element has a box-shaped form corresponding in at least one respect to a shape of the first coating.

7. The coupling arrangement according to claim 1, wherein the PCB has a longitudinal extension.

8. The coupling arrangement according to claim 7, wherein the PCB comprises a plurality of groups of components, wherein the groups of components are positioned at a distance from each other along the longitudinal extension of the PCB.

9. The coupling arrangement according to claim 7, wherein the volume element has a longitudinal extension corresponding to the longitudinal extension of the PCB.

10. The coupling arrangement according to claim 1, wherein the PCA comprises an adhesive layer between the volume element and the first coating.

11. The coupling arrangement according to claim 1, wherein the PCB is a flexible printed circuit board.

12. A touch sensitive panel defining a touch surface, wherein the touch sensitive panel comprises a coupling arrangement according to claim 1.

13. A touch sensitive system comprising a touch sensitive panel according to claim 12, wherein the printed circuit assembly is attached to the touch sensitive panel along the periphery of said touch surface;
a control unit connected to at least one integrated circuit in one or more groups and configured to control operation of the components in each of said one or more groups.

14. The touch sensitive system according to claim 13, wherein said touch sensitive system is based on Frustrated Total Internal Reflection.
